(19) United States
(12) Patent Application Publication
(10) Pub. No.: US 2010/0081255 A1
(43) Pub. Date: Apr. 1, 2010

(54) Methods for reducing defects through selective laser scribing

(76) Inventor: Erasenthiran Poonjolai, Chandler, AZ (US)

Correspondence Address: INTEL CORPORATION;c/o CPA Global, P.O. BOX 52050, MINNEAPOLIS, MN, 55402, US

(21) Appl. No.: 12/286,247

(22) Filed: Sep. 29, 2008

(51) Int. Cl. H01L 21/00

(52) U.S. Cl. 438/462; 257/E21.532

(57) ABSTRACT

Embodiments of an apparatus and methods of reducing defects through selective laser scribing are described herein. Other embodiments may be described and claimed.

### FIELD OF THE INVENTION

The field of invention relates generally to the field of microelectronic devices and, more specifically but not exclusively, relates to semiconductor integrated circuit packaging.

### BACKGROUND INFORMATION

Electronic devices are typically combined with a workpiece and assembled in a package that is soldered or connected to a printed circuit board prior to use. Typically, a number of identical electronic devices are first formed on a single wafer. In some instances, up to several thousand identical electronic devices are formed on the wafer. Once formed, each of the electronic devices is electrically tested and sorted. Next, the wafer is sliced and diced to produce individual wafer portions known as die or chips. Each die or chip contains an individual device, such as an integrated circuit, a microprocessor, or other electronic device. Each die also includes leads, such as pins or balls, which are formed on the surface of the die.

In some instances, the cut lines for slicing and dicing a wafer into individual chips or die are scribed using a laser. Laser scribing is most often used on newer silicon devices incorporating fragile high performance dielectric materials. Laser scribing precedes singulation (slicing and dicing the wafer into individual chips or die) with a saw blade. The laser scribe process may remove some of the fragile materials without leaving mechanical defects in the device edge that can propagate into the electronic device during singulation and/or packaging. However, use of a laser scribe may also create an irregular and porous topography prior to singulation, leading to defects when exposing the topography to mechanical stress during singulation and/or packaging.

### BRIEF DESCRIPTION OF THE DRAWINGS

The present invention is illustrated by way of example and not as a limitation in the figures of the accompanying drawings, in which

FIG. 1 is a schematic view of a laser scribing and cutting mechanism, according to an embodiment of the invention.

FIG. 2 is a cross-sectional illustration of two overlapping laser pulses impinging a surface of a wafer.

FIG. 3 is a cross-sectional illustration of three overlapping laser pulses impinging a surface of a wafer.

FIG. 4 is a top view illustration of a wafer exposed to laser ablation of streets between wafer die.

FIG. 5 is a cross-sectional illustration through section line A-A of the wafer of FIG. 4 with an ablation region formed in the wafer.

FIG. 6 illustrates an alternate embodiment of a wafer with test structures formed on streets between the die.

FIG. 7 is a flowchart describing an embodiment of a fabrication process used to reduce defectivity during singulation.

### DETAILED DESCRIPTION

Methods for reducing defects through selective laser scribing are described in various embodiments. In the following description, numerous specific details are set forth such as a description of an efficient method to form a normalized wafer scribe on a wafer to reduce defects during a singulation process.

It would be an advance in the art of wafer singulation and packaging to reduce defects such as front side die chipping while improving edge die monitor yield. Existing methods for singulating a wafer by first ablating a surface using multiple passes of laser pulses can create an irregular scribe surface comprising weak and porous regions. These regions may cause front side chips and micro-cracks that can propagate into the die when applying mechanical stress during the saw process and/or during packaging. Further, multiple passes of the laser scribe over some areas such as scribe street intersections combined with laser scribing of test structures with disparate material types and topographies along a scribe line can exacerbate an already irregular surface, making the die even more prone to defects formed during a saw process.

One or more methods to reshape and strengthen the laser scribe while accounting for test structures and scribe patterning of a wafer surface through controlled energy density of a series of laser pulses can enhance and normalize the remaining scribe structure prior to singulation. These methods correlate the materials and architecture of test structures along a laser scribe path or street while avoiding multiple scribe passes in common areas, such as intersections, by synchronizing the laser path with a scribe pattern and by controlling an energy density applied such as by changing ablation velocity and z-focus height to provide uniform ablation depth and width. As a result, a normalized wafer scribe may be applied over a wafer surface independent of scribe pattern and test structure layout.

One such method for scribing a wafer with a laser comprises ablating a surface of the wafer with the laser to form a heat affected zone (HAZ). Ablating the wafer surface adjacent to the trench to modify a profile of the trench and form an irregular region, the irregular region comprising a low density portion with an irregular profile. Ablating the irregular region to recast the low density portion and to reshape the irregular profile, then modulating the laser to provide a normalized wafer scribe on the wafer.

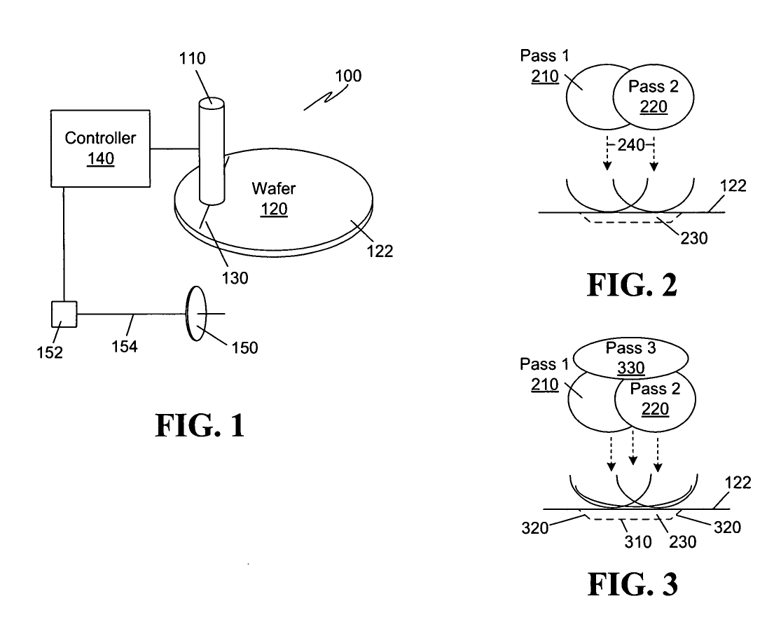

Turning now to the figures, the illustration in FIG. 1 is a schematic view of a laser scribing and cutting mechanism 100 and a wafer 120, according to an embodiment of the invention. The laser scribing and cutting mechanism 100 includes a laser 110. The laser 110 is positioned so that it can produce individual pulses of laser energy that is directed at a wafer surface 122 to impinge the wafer surface 122 with the pulses of laser energy having a pulse frequency between 1 to 80,000 kilo-hertz (KHz). An energy profile comprising an energy intensity and diameter of the beam required is dependent on material properties and structure of the wafer 120 and any elements such as alignment marks or test structures at or near the wafer surface 122. In one embodiment, a wavelength of the laser may range approximately between 1 to 1064 nanometers (nm). A diameter of the beam may similarly range substantially between 1 to 200 microns (μm). In another embodiment, an ion beam or a gas cluster ion beam is used to scribe the wafer surface 122 using a reactive and/or erosion mechanism.

The laser 110 is also movable so that multiple laser pulses can be placed in a continuous line along the surface of the wafer 120. On the surface of wafer 120 there is a line 130 which is merely representative of a scribe line. The laser 110 is connected to a controller 140. The controller 140 controls movement of the laser 110 with respect to the surface of the wafer 120. The controller 140, in one embodiment, can move the laser 110 over the surface of the wafer 120. In an alternative embodiment, the wafer 120 may be moved with respect to the laser 110. The controller 140 is capable of controlling movements of the laser 110 with respect to the wafer 120 in either embodiment. The laser scribing and cutting mechanism 100 also includes a saw wheel or grinding wheel 150 having a kerf. The saw or grinding wheel 150 is typically configured with a diamond surface so that it can cut the material of the wafer 120 to singulate the wafer 120 into a die.

The die may be a microelectronic device such as a processor that may include baseband and applications processing functions and utilize one or more processor cores and/or firmware and hardware in an Application Specific Integrated Circuit (ASIC) device. In an embodiment where the die is a processor, the die may process functions that fetch instructions, generate decodes, find operands, and perform appropriate actions, then store results. The use of multiple cores may allow one core to be dedicated to handle application specific functions such as, for example, graphics, modem functions, etc. Alternatively, the multiple processor cores may allow processing workloads to be shared across the processor cores. In another embodiment, the die is another microelectronic device such as a system on a chip, a communications chip, or a graphics chip.

Wafer 120 is made of a fragile dielectric material or similar hard material and, therefore, the saw or grinding wheel 150 must include a hard substance such as diamond. The saw or grinding wheel 150 is turned by motor 152 attached to a shaft 154. The shaft 154 is attached to the saw or grinding wheel 150. The motor 152 is also attached to the controller 140. Therefore, the controller 140 can control the speed of rotation of the grinding wheel as well as control the position of the grinding wheel or saw 150 with respect to the wafer 120.

FIG. 2 is a cross-sectional illustration of two overlapping laser pulses impinging a wafer surface 122. The two overlapping laser pulses may occur at two different instances of time, or the two overlapping laser pulses may occur simultaneously or nearly simultaneously in another embodiment. A first laser pulse represented by Pass 1 (210) emitted by the laser 110 impinges the wafer surface 122 and a second laser pulse represented by Pass 2 (220) emitted by the laser 110 overlaps the first laser pulse. In one embodiment, the laser pulses may be applied in a square waveform with a frequency that ranges between milliseconds to femtoseconds.

In this embodiment, the Pass 1 (210) and Pass 2 (220) are used to ablate the wafer surface 122 to form a heat affected zone (HAZ) 230 while removing material from the wafer 120. The laser pulses directed at the wafer surface 122 irradiate the wafer 120, wherein energy from the laser pulses are absorbed by the wafer 120 at or near the wafer surface 122 to heat and remove a portion of the wafer 120 through evaporation or sublimation. A depth over which the laser energy is absorbed is a function of material type of the wafer 120 at or near the wafer surface 122, which may be a uniform material or may be a variety of disparate materials including organic material such as photoresist, one or more metals, and dielectric materials used to form alignment marks, isolation regions, and/or test structures. More particularly, the laser energy absorbed by the wafer 120 depends on the optical properties of the wafer 120 material type and on a wavelength of the laser.

The Pass 1 (210) and Pass 2 (220) impinges the wafer surface 122 in an overlapping pattern where an overlap 240 may be selected to provide between 75% to 95% overlapping coverage between the laser pulses for the dual pass laser ablation as illustrated in FIG. 2.

FIG. 3 is a cross-sectional illustration of three overlapping laser pulses impinging a wafer surface 122. Laser scribing can produce a plume of suspended material from the wafer 120 when the laser pulses the wafer surface 122. When the laser scribe lines are always placed one next to the other to scribe the wafer, the plume associated with the laser scribing process can accumulate on one side of the laser scribe, forming an ablation shelf. Portions of the plume can further settle or deposit on the solder associated with the leads to the circuitry within the die or chip. In some instances, the plume may even result in opens being found as a result of plume deposits on the leads preventing electrical connection to the leads. The silicon debris from the laser scribe plume that interferes with electrical interconnection between the die and a package results in yield losses and also potentially increases the reliability failure rate.

A third laser pulse, Pass 3 (330) may be applied to overlap both Pass 1 (210) and Pass 2 (220) to provide a more uniform HAZ 230 with a cross-section that may resemble a trench with a substantially uniform trench bottom 310 and laterally opposing trench sidewalls 320. The trench sidewalls 320 may form an obtuse angle in reference to the trench bottom 310 or the trench sidewalls 320 may be substantially vertical in reference to the trench bottom 310. Application of a third pass may be applied to create a preferred HAZ 230 profile, wherein regions of a HAZ 230 from a dual pass process with insufficient overlap gap 240 may comprise an irregular region comprising a porous or low density portion with an irregular profile. The irregular profile may be characterized by a sharp and/or jagged topography that is prone to forming cracks when exposed to mechanical stress. Ablating the irregular region to recast and harden the low density portion, for example as a result of a porous material formed during Pass 1 (210) and/or Pass 2 (220) and to reshape the irregular profile with the Pass 3 (330) may be used to avoid defects that would otherwise be formed in the wafer 120 during a singulation process. In another embodiment (not shown), a Pass 4 and a Pass 5 may be employed in an overlapping manner to further recast and harden low density portions formed during Pass 1 (210) and Pass 2 (220).

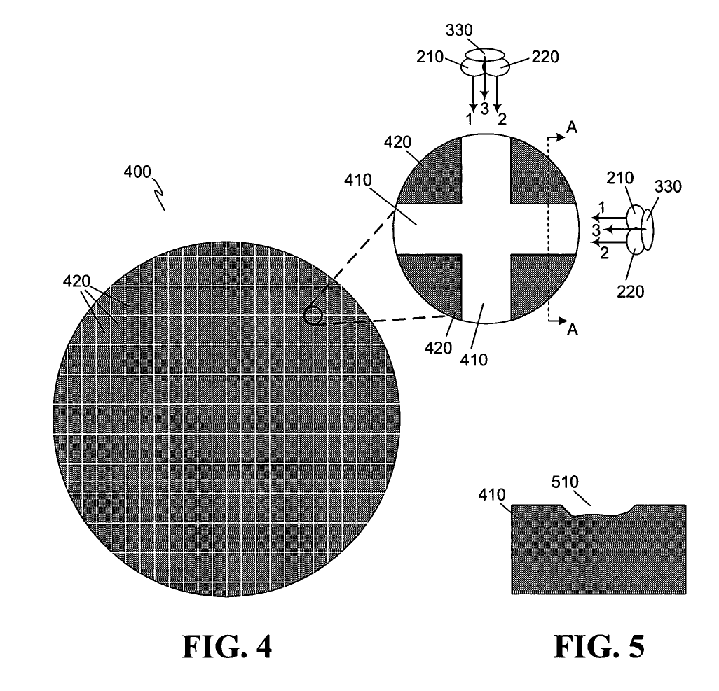

FIG. 4 is a top view illustration of a wafer 120 exposed to laser ablation of streets 410 between wafer die 420. The streets 410 are depicted as white lines in FIG. 4 and the areas between the streets 410 represent the wafer die 420. The Pass 1 (210) and Pass 2 (220) and Pass 3 (330) may be configured to extend across an entire width of the street 410 as shown in FIG. 4 or may be selectively limited to only a portion of the width of the street 410 and aligned with the center of the street 410. In another embodiment, the Pass 1 (210) and Pass 2 (220) and Pass 3 (330) may be limited to only a portion of the width of the street 410 and positioned near a perimeter or edge of the die 420. In a further embodiment, the Pass 1 (210) and Pass 2 (220) and Pass 3 (330) may be aligned near the perimeters of two die 420 adjacent to a street 410, resulting in six parallel laser scribe passes common to a single street 410.

In one embodiment, the streets 410 are formed of a consistent material such as silicon or a dielectric layer such as silicon dioxide. In another embodiment, materials in the streets 410 of the wafer 120 comprise a standard or high performance dielectric material, one or more metals, an organic layer, and/or some combination thereof. Laser ablation removes some of the fragile materials at or near the top surface of the wafer 120 without leaving mechanical defects along an edge or boundary of the wafer die 420.

Without laser scribing, mechanical defects could propagate into the wafer die 420 under normal mechanical loads and cause failures of the wafer die 420. These mechanical defects may not propagate into an active device area of the wafer die 420 until after the chip or die is packaged and leaves the factory. Laser scribing also prevents long, thin, fragile dielectric and embedded copper (Cu) metal traces from peeling up and becoming entangled in the leads that are attached to the wafer die 420. In many instances, the leads are interconnect bumps arranged in an array and are also called a ball grid array. Other types of leads can also be used in the wafer die 420. In a further embodiment (not shown), the street 410 comprises a region of a first material such as or silicon dioxide or silicon nitride in a line positioned substantially in the middle of the street 410 and bordered on each side of the line by moat regions parallel to guard rings that border the edge of the wafer dies 420. Selective use of the moats and/or guard rings offer further protection against defects that may propagate into the wafer die 420 under normal mechanical loads and cause failures of the wafer die 420.

FIG. 5 is a cross-sectional illustration through section line A-A of the wafer 120 of FIG. 4 with an ablation region 510 formed in the wafer 120. The ablation region 510 is one embodiment of the heat affected zone 230 of FIG. 2 produced using a three pass ablation process. Here the wafer 120 is impinged with laser pulses Pass 1 (210) to form a trench (not shown), then impinged along the wafer surface 122 adjacent to the trench with Pass 2 (220) to modify a profile of the trench and form an irregular region (not shown), the irregular region comprising a low density portion with an irregular profile. A third ablation Pass 3 (330) recasts the low density portion and reshapes the irregular profile to form the ablation region 510.

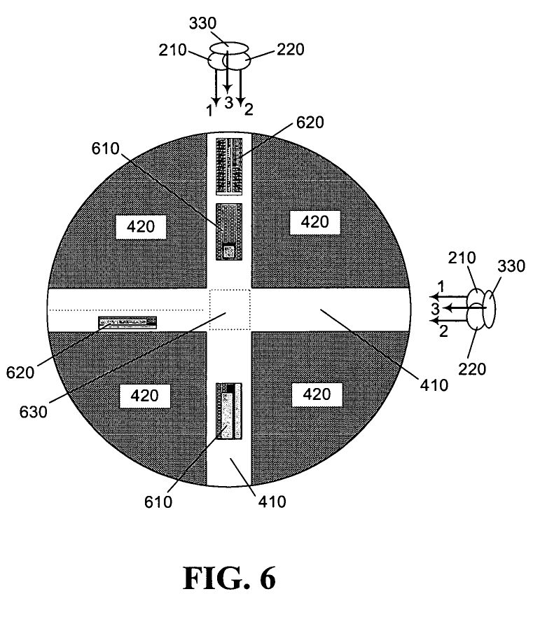

FIG. 6 illustrates an alternate embodiment of a wafer 120 with alignment marks 610 and test structures 620 formed on streets 410 between the wafer die 420. The test structures 620 are microelectronic devices that are fabricated by the same processes used to manufacture semiconductor integrated circuit products, such as the wafer die 420. The test structures 620 may be used to measure selected material, process or tool parameters by means of electrical tests. Further, the test structures 620 can be used to evaluate semiconductor materials, to determine and monitor output process parameters, to identify and quantify yield-limiting defects and to assess processing tool performance. Materials used to form the test structures 620 may be one or more of conductors, semiconductors, and isolation layers configured in a three dimensional pattern on the wafer. The alignment marks 610 may be used to align a feature on a wafer to a feature on a photomask, used in a photolithography process to form the wafer dies 420. The alignment marks 610 may be etched into the wafer 120 or formed as a pattern on the wafer 120 using a dielectric layer or an organic layer. A street intersection 630 is an area of a street where two streets meet, thereby forming an area on the wafer surface 122 where the laser ablation of the streets would overlap.

To provide a normalized wafer scribe on the wafer, or a consistent HAZ across the streets 410 of the wafer 120, energy transferred to the wafer is modulated to compensate for elements such as alignment marks 610, test structures 620, photoresist pads or regions comprising photoresist, and isolation regions. An energy density applied by the laser 110 compensates for various elements with varied materials and configurations and is optimized by modulating, for example, an ablation velocity and/or z-focus height (in and out of the page of FIG. 6) to produce a uniform ablation depth and width in the streets 410. Further, layout of the streets 410 is also considered to avoid overlapping of ablation patterns, or to avoid ablating an area such as a street intersection 630 multiple times. In one embodiment, a laser shutter mechanism may be employed to block or otherwise abridge the laser beam to reduce an intensity of the laser beam. The laser scribing and cutting mechanism 100 of FIG. 1 may be programmed or synchronized with a wafer map and/or reticle layout to compensate for a test structure, alignment mark layout, and/or photoresist pad layout and scribe pattern to provide a consistent and normalized wafer scribe pattern over the wafer 120.

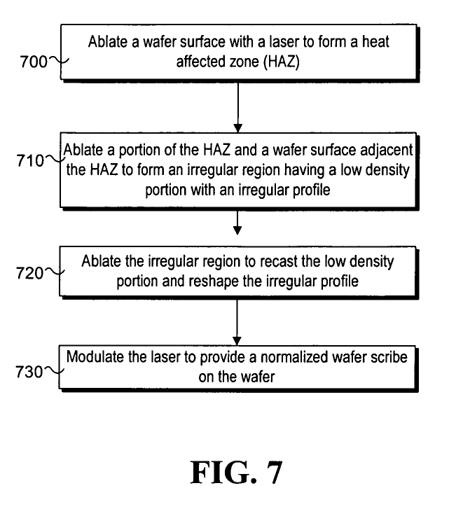

FIG. 7 is a flowchart describing an embodiment of a fabrication process used to reduce defectivity during singulation. In element 700, the wafer surface 122 is ablated with a laser beam to form a heat affected zone (HAZ) 230. A portion of the HAZ (230) is ablated and the wafer surface 122 adjacent to the HAZ 230 to form an irregular region having a low density portion with an irregular profile in element 710. The irregular region is ablated in element 720 to recast and harden the low density portion and reshape the irregular profile. The laser beam is modulated in element 730 to provide a normalized wafer scribe over the wafer surface 122.

The operation discussed herein may be generally facilitated via execution of appropriate firmware or software embodied as code instructions on the host processor and microcontroller, as applicable. Thus, embodiments of the invention may include sets of instructions executed on some form of processing core or otherwise implemented or realized upon or within a machine-readable medium. A machine-readable medium includes any mechanism for storing or transmitting information in a form readable by a machine (e.g., a computer). For example, a machine-readable medium can include an article of manufacture such as a read only memory (ROM); a random access memory (RAM); a magnetic disk storage media; an optical storage media; and a flash memory device, etc. In addition, a machine-readable medium may include propagated signals such as electrical, optical, acoustical or other form of propagated signals (e.g., carrier waves, infrared signals, digital signals, etc.).

A plurality of embodiments of an apparatus and methods for reducing defects through selective laser scribing have been described. The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations.

However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method for scribing a wafer with a laser, comprising:
ablating a wafer surface with the laser to form a heat affected zone (HAZ);
ablating a portion of the HAZ and the wafer surface adjacent to the HAZ to form an irregular region, the irregular region comprising a low density portion with an irregular profile;
ablating the irregular region to recast and harden the low density portion and reshape the irregular profile; and
modulating the laser to provide a normalized wafer scribe on the wafer.

2. The method for scribing the wafer of claim 1, wherein the irregular profile is formed from substantially overlapping ablations.

3. The method for scribing the wafer of claim 2 wherein a width of the substantially overlapping ablations is in a range of 1 to 100 microns.

4. The method for scribing the wafer of claim 1, wherein a wafer scribe width is greater than the width of a saw blade kerf.

5. The method for scribing the wafer of claim 1, wherein the laser is modulated in response to a scribe pattern.

6. The method for scribing the wafer of claim 1, wherein the heat affected zone is formed near the edge of the wafer die.

7. The method for scribing the wafer of claim 6, wherein a first energy profile is used to form the HAZ and a second energy profile is used to form the irregular region.

8. A computer readable medium containing instructions for causing a suitably programmed computer to execute the method for scribing the wafer of claim 1.

9. The method for scribing the wafer of claim 1, wherein a beam diameter of the laser ranges substantially between 1 and 200 μm.

10. A method for singulating die from a wafer, comprising:
forming a normalized wafer scribe on the wafer, the normalized wafer scribe formed by impinging the wafer with a laser a plurality of times in an overlapping pattern in response to a scribe pattern, a test feature layout, and a wafer composition; and
sawing the wafer along the normalized wafer scribe.

11. The method for singulating die from the wafer of claim 10, wherein the wafer is sawed with a saw blade and a width of the normalized wafer scribe is greater than a width of a saw blade kerf.

12. The method for singulating die from the wafer of claim 10, wherein a beam diameter of the laser ranges substantially between 1 and 200 μm.

13. The method for singulating die from the wafer of claim 10, wherein a width of the normalized wafer scribe is in a range of 1 to 100 microns.

14. A computer readable medium containing instructions for causing a suitably programmed computer to execute the method of claim 10.

15. A method for laser scribing a wafer, comprising:
laser scribing a first continuous line;
laser scribing a second continuous line overlapping the first continuous line;
laser scribing a third continuous line, the third continuous line overlapping the first continuous line and the second continuous line; and
modulating the laser scribe in response to a scribe pattern, a test feature layout, and a wafer material composition.

16. The method for laser scribing the wafer of claim 15, wherein the first continuous line, the second continuous line and the third continuous line are formed from overlapping pulses from a laser.

17. The method for laser scribing the wafer of claim 15, wherein the first continuous line, the second continuous line and the third continuous line overlap are in an area having a width greater than the width of a kerf of a saw blade.

18. The method for laser scribing the wafer of claim 15, further including sawing the wafer along the third continuous line with a saw blade.

19. The method for scribing the wafer of claim 15, wherein a beam diameter of the laser scribe ranges substantially between 1 and 200 μm.

20. A computer readable medium containing instructions for causing a suitably programmed computer to execute the method of claim 15.
